(19) United States
(12) Patent Application Publication
(10) Pub. No.: US 2016/0306461 A1
(43) Pub. Date: Oct. 20, 2016

(54) TOUCH PANEL AND METHOD FOR MANUFACTURING THE SAME

(71) Applicant: Samsung Display Co., Ltd., Yongin-si (KR)

(72) Inventor: Koichi SUGITANI, Hwaseong-si (KR)

(21) Appl. No.: 14/961,291

(22) Filed: Dec. 7, 2015

(30) Foreign Application Priority Data
Apr. 17, 2015 (KR) 10-2015-0054581

(51) Int. Cl. G06F 3/044; C23C 14/58; G06F 3/047

(52) U.S. Cl. CPC G06F 3/044; G06F 3/047; C23C 14/5806; G06F 2203/04103; G06F 2203/04111

(57) ABSTRACT

A touch panel and a method for manufacturing the same. The touch panel includes a uniaxially oriented base film and a transparent electrode pattern layer formed on the base film. End protective films are attached to opposite ends of the base film in the same direction as a stretched direction. The end protective films are uniaxially oriented in a direction perpendicular to the stretched direction of the base film.

### CROSS-REFERENCE TO RELATED APPLICATION

This application claims priority from and the benefit of Korean Patent Application No. 10-2015-0054581 filed on Apr. 17, 2015, which is hereby incorporated by reference for all purposes as if fully set forth herein.

### BACKGROUND

1. Field

Exemplary embodiments relate to a touch panel and a method for manufacturing the same.

2. Discussion of the Background

Electronic devices, such as a liquid crystal display (LCD), an organic light emitting diode display (OLED display), and an electrophoretic display may include a touch sensing function that may interact with a user. The touch sensing function may sense a change in pressure, charge, light, and the like, which are applied to a screen by a display, whenever an observer approaches or contacts his/her finger, a touch pen, or the like, to a touch surface so as to write characters or draw pictures, thereby determining contact information regarding whether objects approach or contact the touch surface, the contact positions, and the like.

The touch sensing functions of several electronic devices may be implemented by a touch sensor. The touch sensor may be classified into various types, such as a resistive type, a capacitive type, an electro-magnetic type (EM), and an optical type.

For example, a capacitive type touch sensor includes a sensing capacitor formed of a plurality of sensing electrodes capable of transferring a sensing signal, and senses a change in capacitance or a charged state of charge of the sensing capacitor generated when a conductor, such as a finger, approaches the touch sensor to detect the touch, the touch position, and the like. The capacitive type touch sensor may include a plurality of touch electrodes, which are disposed in a touch sensing region capable of sensing a touch, and touch wirings which are connected to the touch electrodes. The touch wiring may transfer a sensing input signal to the touch electrode or transfer a sensing output signal of the touch electrode, which is generated depending on a touch to a touch driver.

The touch sensor may be embedded in the display device (in-cell type), directly u) formed on an outer surface of the display device (on-cell type), or added to the display device as a separate touch sensor unit (add-on cell type). In particular, in the case of a flexible display device, a method for forming a separate touch sensor apparatus in a film or plate form, in which the touch sensor is formed, and then attaching the touch sensor apparatus on a display panel (add-on cell type), has been often used.

When various electronic devices, such as the display device and the touch sensor apparatus use a glass substrate that is relatively heavy and easily broken, the electronic devices have limitations regarding portability and size because of a large screen display. Therefore, a flexible electronic device using a film having reduced weight, strong impact resistance, and high flexibility as a substrate has been actively developed in recent years.

However, the substrate formed of the film typically has a problem in that cracks occur in edge regions of the substrate during a process of forming the touch sensor and the wiring patterns on the substrate, and thus, the touch performance of the touch panel deteriorates.

The above information disclosed in this Background section is only for enhancement of understanding of the background of the inventive concept, and, therefore, it may contain information that does not form the prior art that is already known in this country to a person of ordinary skill in the art.

### SUMMARY

Exemplary embodiments provide a touch panel and a method for manufacturing the same having an advantage of preventing cracks from being formed at opposite ends of a base film in the same direction as a stretched direction.

Additional aspects will be set forth in the detailed description which follows, and, in part, will be apparent from the disclosure, or may be learned by practice of the inventive concept.

An exemplary embodiment discloses a touch panel including a uniaxially oriented base film and a transparent electrode pattern layer disposed on the base film, wherein protective films that are uniaxially oriented in a direction perpendicular to a stretched direction of the base film are attached to opposite ends of the base film in the same direction as the stretched direction.

An exemplary embodiment also discloses a touch panel including a uniaxially oriented base film and a transparent electrode pattern layer disposed on the base film. Opposite ends of the base film in the same direction as a stretched direction are provided with heat treated regions.

An exemplary embodiment also discloses a method for manufacturing a touch panel including attaching a uniaxially oriented base film on a substrate and heat treating predetermined regions of opposite ends in the same direction as a stretched direction of the base film.

The foregoing general description and the following detailed description are exemplary and explanatory and are intended to provide further explanation of the claimed subject matter.

### BRIEF DESCRIPTION OF THE DRAWINGS

The accompanying drawings, which are included to provide a further understanding of the inventive concept, and are incorporated in and constitute a part of this specification, illustrate exemplary embodiments of the inventive concept, and, together with the description, serve to explain principles of the inventive concept.

FIG. 1 is a cross-sectional view of the touch panel according to an exemplary embodiment of the present invention.

FIG. 2 is a diagram illustrating a region of opposite ends in the same direction as a stretched direction of a base film.

FIG. 3, FIG. 4, FIG. 5, FIG. 6, FIG. 7, FIG. 8, FIG. 9, and FIG. 10 are diagrams sequentially illustrating a process of forming the touch panel of FIG. 1.

FIG. 11 is a diagram illustrating a cross section of a touch panel according to another exemplary embodiment of the present invention.

FIG. 12, FIG. 13, and FIG. 14 are diagrams sequentially illustrating a process of forming the touch panel of FIG. 11.

FIG. 15A and FIG. 15B are diagrams illustrating that cracks are suppressed from occurring at ends of a base film of the FIG. 1.

FIG. 16A, FIG. 16B, and FIG. 16C are diagrams illustrating that cracks are suppressed from occurring at the ends of the base film of the FIG. 11.

FIG. 17 is a photograph illustrating magnified edge regions of a transparent electrode pattern layer in the touch panel of FIG. 1.

### DETAILED DESCRIPTION OF THE ILLUSTRATED EMBODIMENTS

In the following description, for the purposes of explanation, numerous specific details are set forth in order to provide a thorough understanding of various exemplary embodiments. It is apparent, however, that various exemplary embodiments may be practiced without these specific details or with one or more equivalent arrangements. In other instances, well-known structures and devices are shown in block diagram form in order to avoid unnecessarily obscuring various exemplary embodiments.

In the accompanying figures, the size and relative sizes of layers, films, panels, regions, etc., may be exaggerated for clarity and descriptive purposes. Also, like reference numerals denote like elements.

When an element or layer is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. For the purposes of this disclosure, “at least one of X, Y, and Z” and “at least one selected from the group consisting of X, Y, and Z” may be construed as X only, Y only, Z only, or any combination of two or more of X, Y, and Z, such as, for instance, XYZ, XYY, YZ, and ZZ. Like numbers refer to like elements throughout. As used herein, the term “and/or” includes any and all combinations of one or more of the associated listed items.

Although the terms first, second, etc. may be used herein to describe various elements, components, regions, layers, and/or sections, these elements, components, regions, layers, and/or sections should not be limited by these terms. These terms are used to distinguish one element, component, region, layer, and/or section from another element, component, region, layer, and/or section. Thus, a first element, component, region, layer, and/or section discussed below could be termed a second element, component, region, layer, and/or section without departing from the teachings of the present disclosure.

Spatially relative terms, such as “beneath,” “below,” “lower,” “above,” “upper,” and the like, may be used herein for descriptive purposes, and, thereby, to describe one element or feature's relationship to another element(s) or feature(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the exemplary term “below” can encompass both an orientation of above and below. Furthermore, the apparatus may be otherwise oriented (e.g., rotated 90 degrees or at other orientations), and, as such, the spatially relative descriptors used herein interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this disclosure is a part. Terms, such as those defined in commonly used dictionaries, should be interpreted as having a meaning that is consistent with their meaning in the context of the relevant art and will not be interpreted in an idealized or overly formal sense, unless expressly so defined herein.

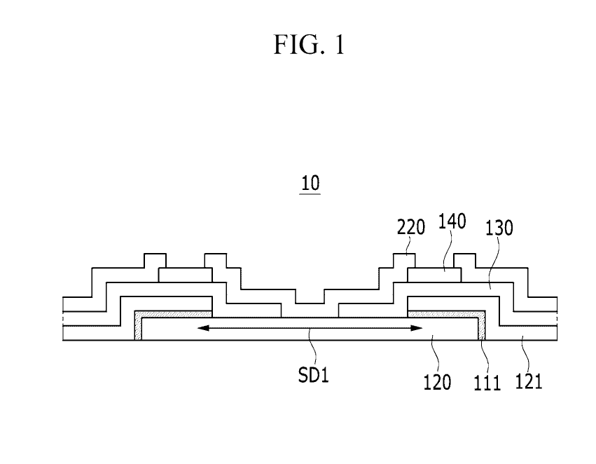

FIG. 1 is a diagram illustrating a cross section of the touch panel 10 according to an exemplary embodiment of the present invention.

Referring to FIG. 1, a touch panel 10 includes a base film 120, an end protective film 121, a transparent electrode pattern 130, a wiring pattern layer 140, and a passivation layer 220.

Hereinafter, each component of the touch panel according to the exemplary embodiment will be described in detail.

As the base film 120, a plastic film having high flexibility may be used. For example, a polycarbonate (PC) film, a polyethyleneterephthalate (PET) film, a polyethylenenaphthalate (PEN) film, a polyarylate (PAR) film, a polyetherimide (PEI) film, a polyethersulfone (PES) film, a polyimde (PI) film, or the like may be used. The base film 120 may be a uniaxially oriented film. The uniaxially oriented film may further improve the stiffness of the film. In particular, as the base film 120, a uniaxially oriented polycarbonate film may be used having an excellent optical function.

The end protective films 121 are attached to a predetermined region of each edge of the base film 120. In more detail, the uniaxially oriented end protective films 121 are attached in a direction SD2 to both ends of the base film 120 in the same direction as the stretched direction SD1, where the direction SD2 is perpendicular to a stretched direction SD1 of the base film.

In this case, the end protective film 121 may be a polycarbonate film, a polyethyleneterephthalate (PET) film, a polyethylenenaphthalate film, a polyarylate film, a polyetherimide film, a polyethersulfone film, or a polyimde film, but is not limited thereto.

The base film 120 and the end protective film 121 may be made of the same material.

The inventors have conducted experiments which indicate that cracks may occur at opposite ends in the same direction as the stretched direction of the base film 120 during the process of manufacturing a touch panel due to the permeation of solvent components included in a second photosensitive coating composition used in the process for forming the transparent electrode pattern layer 130. The present invention attempts to prevent these cracks.

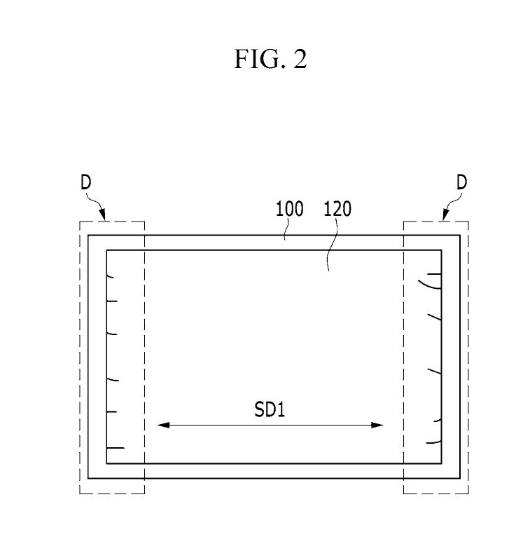

To prevent the cracks from occurring, as illustrated in FIG. 1, the end protective films 121 stretched in a direction SD2 perpendicular to the stretched direction SD1 of the base film 120 are attached to both end regions D (see FIG. 2) in the same direction as the stretched direction SD1 of the base film 120 to cover an end side wall, thereby preventing cracks from occurring at the end in the stretched direction of the base film 120 due to the permeation of a chemical component such as a solvent included in a second photosensitive coating composition during the photoresist process.

The transparent electrode pattern layer 130 is then formed on the base film 120. The transparent electrode pattern layer 130 forms the touch sensor, which may sense a touch by various methods. The touch sensor may be one of various types of touch sensors, such as a resistive type, a capacitive type, an electro-magnetic type (EM), and an optical type.

In this case, a material forming the transparent electrode pattern layer 130 may include transparent conductive oxides, such as indium tin oxide (ITO) or indium zinc oxide (IZO), but is not limited thereto. Therefore, a material forming the transparent electrode pattern layer 130 may include at least one of metal nanowire, conductive polymers such as PEDOT, metal mesh, and transparent conductive materials such as carbon nanotubes (CNT). Further, when the transparent electrode pattern layer 130 includes a silver nanowire (AgNW) material, the transparent electrode pattern layer 130 may further include an AgNW layer and an upper conductive layer positioned thereon, in which the upper conductive layer may include ITO, IGO, GTO, etc.

A wiring pattern layer 140 connected to a transparent electrode pattern is then formed on the transparent electrode pattern layer 130. A voltage may be applied through the wiring pattern layer 140, and thus, a signal may be transferred to the transparent electrode pattern layer 130. In this case, a material forming the wiring pattern layer 140 may include low resistance materials, such as molybdenum (Mo), silver (Ag), titanium (Ti), copper (Cu), aluminum (Al), or molybdenum/aluminum/molybdenum (Mo/Al/Mo).

The passivation layer 220 is formed on the transparent electrode pattern layer 130 and the wiring pattern layer 140. As illustrated in FIG. 1, the passivation layer 220 is formed to expose the wiring pattern layer 140 to apply a voltage, and, as a result, a signal may be transferred to the transparent electrode pattern layer 130.

In this case, the passivation layer 220 may include insulating materials such as inorganic materials including silicon nitride (SiNₓ), silicon oxide (SiO₂), or aluminum oxide (AlOₓ), etc., or organic materials including polyimide, polyester, and acryl, etc., and serve to passivate the transparent electrode pattern layer 130 and the wiring pattern layer 140 and insulate the transparent electrode pattern layer 130 and the wiring pattern layer 140 from other layers.

As described above, in the touch panel 10 according to an exemplary embodiment, the end protective films 121 may be attached to opposite ends of the base film 120 in the same direction as the stretched direction SD1 to significantly reduce the occurrence of cracks at both ends of the base film 120.

This is because the permeation of a solvent component, etc., included in the composition used to form the second photosensitive coating layer 210 during the process of forming the transparent electrode pattern layer 130 may be removed by the presence of the end protective films 121.

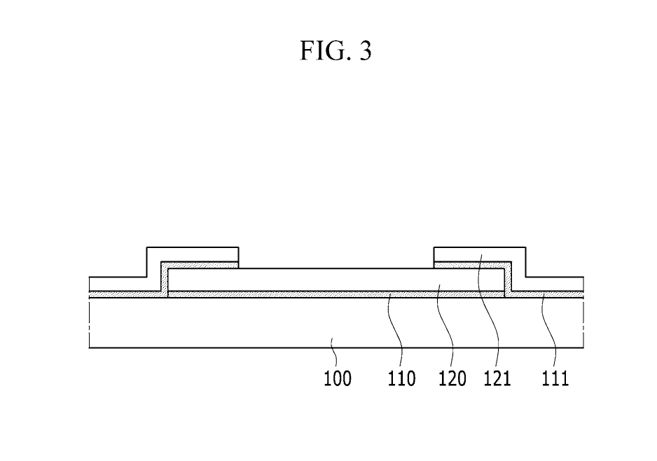

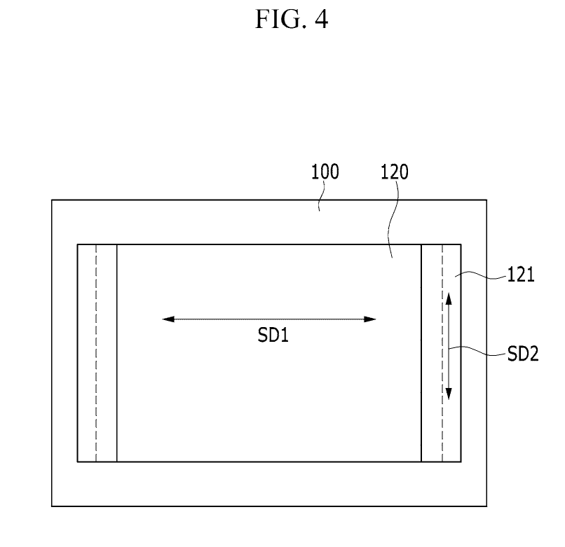

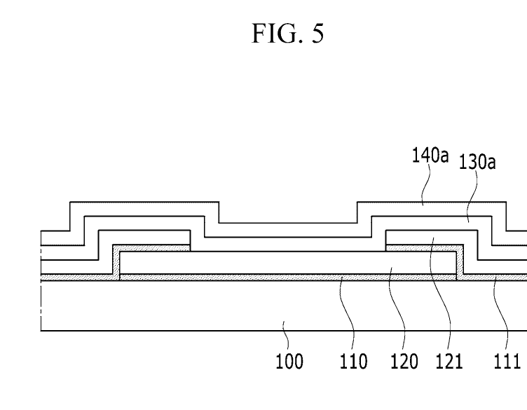

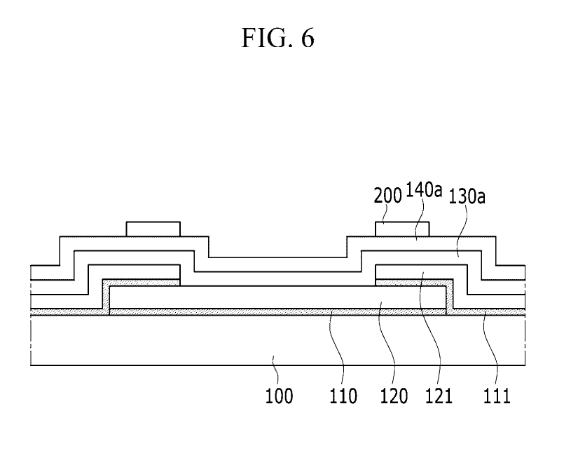

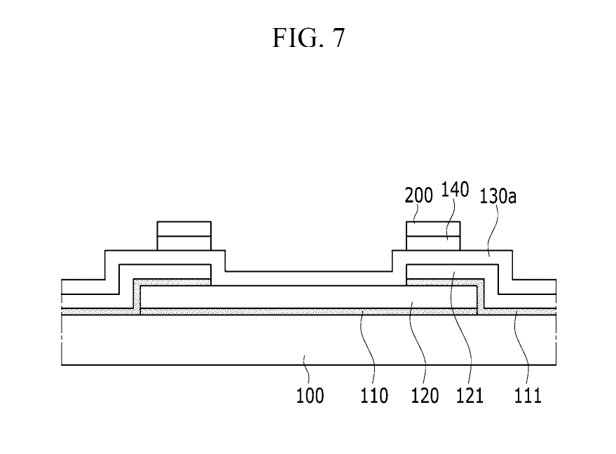

An exemplary embodiment of the process of manufacturing the touch panel having the configuration illustrated in FIG. 1 will be described in detail with reference to FIGS. 3 to 10.

FIGS. 3 to 10 are diagrams sequentially illustrating a process of forming the touch panel of FIG. 1.

First, as illustrated in FIG. 3, the base film 120 is attached on the substrate 100 by an adhesive 110, and then the end protective films 121 are attached to both ends of the base film 120 by an adhesive 111.

In this case, the substrate 100 is a process substrate for addressing the disadvantage that the base film 120 used to manufacture the touch panel having high flexibility is easily warped and is made of solid materials, such as glass or metal.

The base film 120 is attached on the substrate 100 by the adhesive 110. Any adhesive 110 may be used without limitation, and the base film 120 may be attached using, for example, an aqueous adhesive or a non-aqueous adhesive.

FIG. 4 illustrates a plan view of FIG. 3. Referring to FIG. 4, the end protective film 121 is stretched in the direction SD2 perpendicular to the stretched direction SD1 of the base film 120, and is attached to opposite ends in the same direction as the stretched direction SD1 of the base film 120.

As illustrated in FIG. 5, a transparent electrode layer 130a is deposited on the base film 120 and the end protective film 121. The transparent electrode layer 130a may be formed by sputtering or depositing the foregoing transparent conductive oxide. A metal layer 140a may then be formed by sputtering or depositing the low resistance material on the transparent electrode layer 130a.

Then, as shown in FIG. 6, a first photosensitive coating layer 200 is formed on the metal layer 140a using at least one of a spin coating method, a slit coating method, an inkjet printing method, and a screen printing method. Then, the first photosensitive coating layer 200 is exposed, baked, and developed to form a first photosensitive pattern for forming the wiring pattern layer 140.

The metal layer 140a is then etched to form the wiring pattern layer 140, as illustrated in FIG. 7.

As shown in FIG. 8, a second photosensitive coating layer 210 is then formed on the wiring pattern layer 140 and the transparent electrode layer 130a using at least one of a spin coating method, a slit coating method, an inkjet printing method, and a screen printing method.

As shown in FIG. 9, the second photosensitive coating layer 210 is then exposed, baked, and developed to form a second photosensitive pattern for forming a transparent electrode pattern layer 130. Then, as shown in FIG. 10, the transparent electrode layer 130a is etched to form the transparent electrode pattern layer 130. Here, the etching may be performed by at least one of dry etch and wet etch.

The passivation layer 220 is formed on the transparent electrode pattern layer 130 and the wiring pattern layer 140. In this case, the wiring pattern layer 140 is formed to be exposed as illustrated in FIG. 10 by etching a portion of the passivation layer 220. The touch panel 10 having the cross section structure as illustrated in FIG. 1 may be obtained by removing the substrate 100.

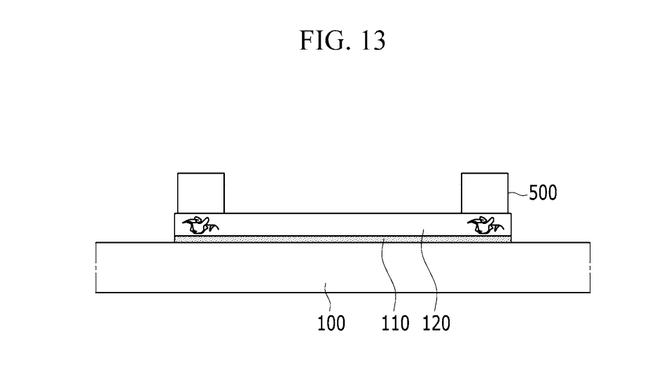

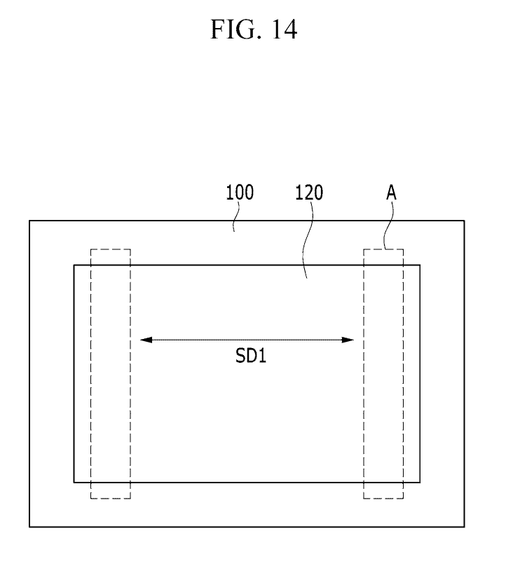

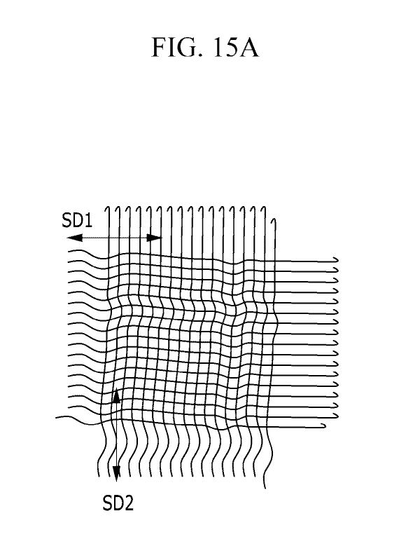

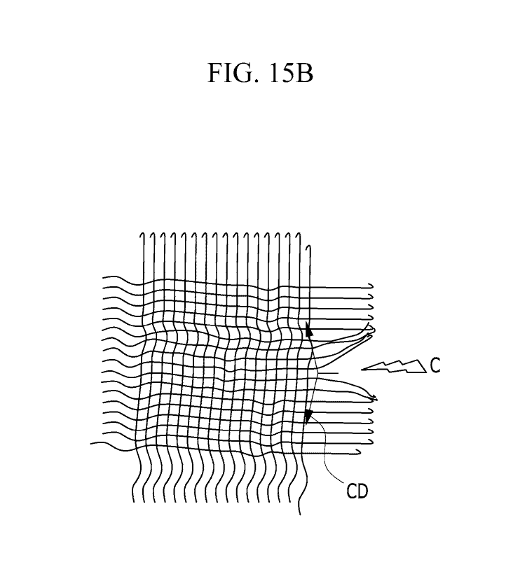

FIGS. 15A and 15B are enlarged views of a process of suppressing cracks from occurring at one end of the base film of FIG. 1. According to an exemplary embodiment, the end protective films 121 stretched in the direction SD2 perpendicular to the stretched direction SD1 of the base film 120 are attached to both ends of the base film 120, and thus, as illustrated in FIGS. 15A and 15B, when a crack C occurs at the end of the base film 120, a cross direction CD of the crack C may be changed along the stretched direction SD2 of the end protective film 121. Therefore, the touch panel according to the exemplary embodiment of the present disclosure may effectively reduce the occurrence of cracks at both ends of the base film by using the above effect.

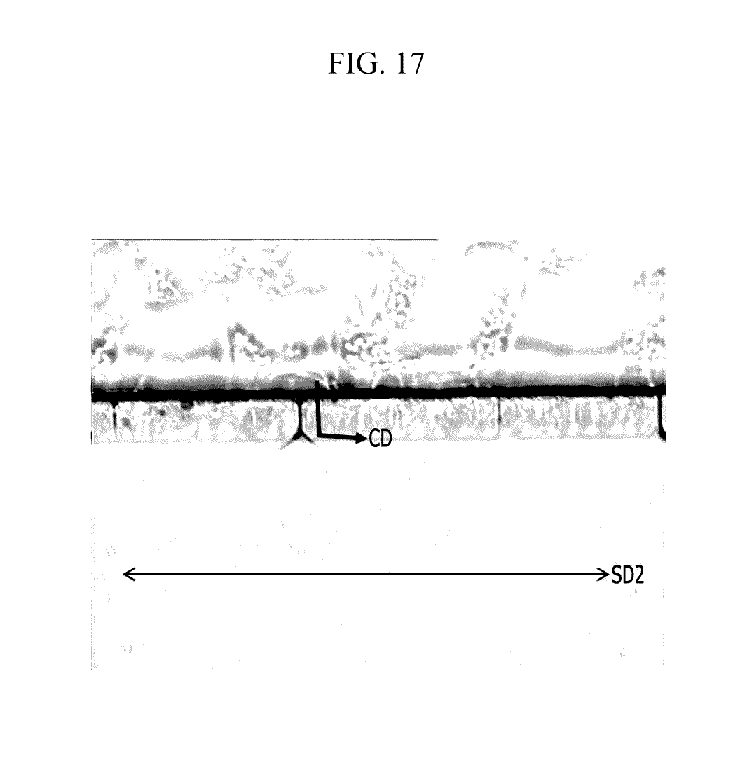

Further, FIG. 17 is an enlarged photographic view of an edge region of the transparent electrode pattern layer of the touch panel having the structure of FIG. 1. It may be more apparently appreciated from FIG. 17 that the cross direction of cracks occurring in the touch panel is changed along the stretched direction SD2 of the end protective film 121. That is, it may be appreciated that the cracks occurring at the end of the base film 120 are progressed into the film and thus are prevented from being enlarged along the stretched direction SD1 of the base film 120.

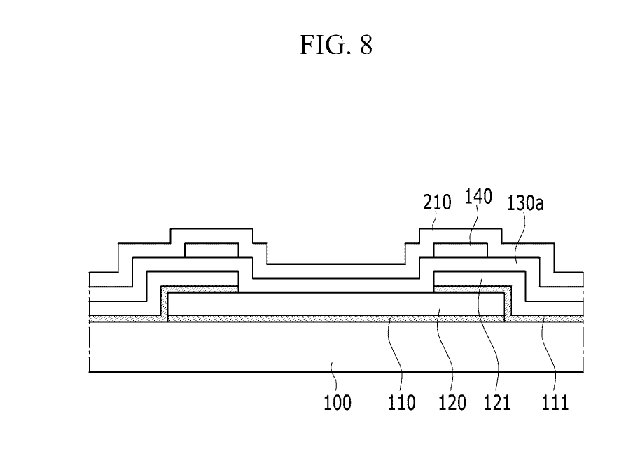

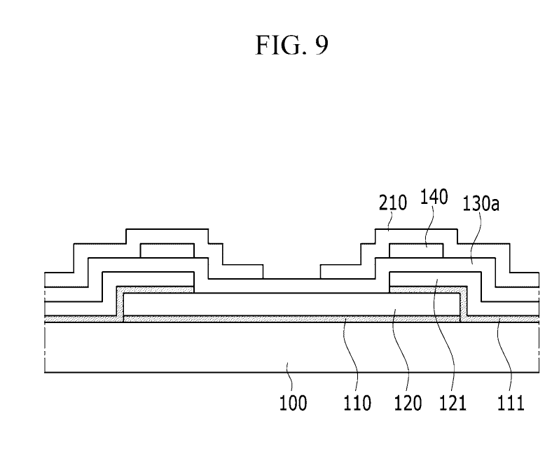

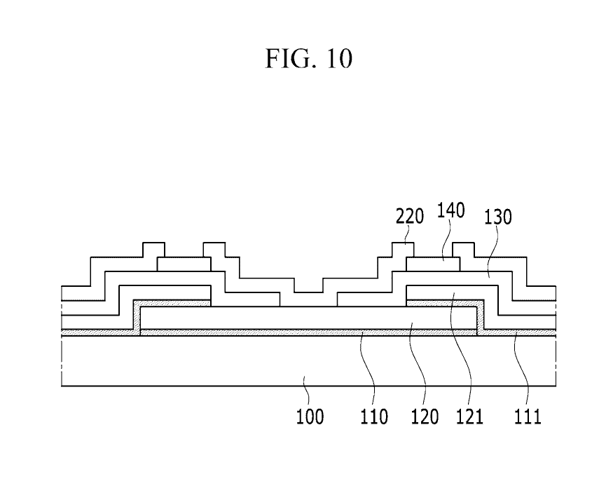

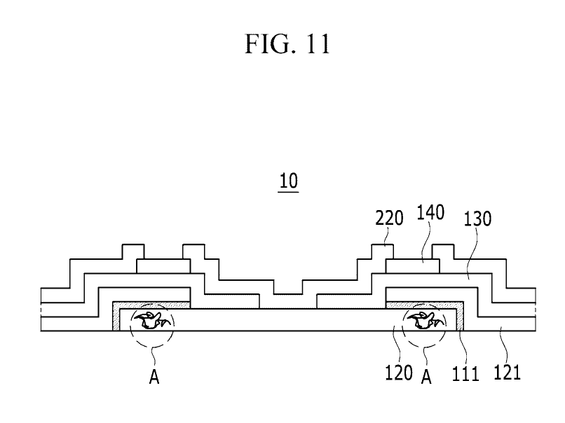

FIG. 11 illustrates a cross section of a touch panel according to another exemplary embodiment of the present invention.

Referring to FIG. 11, a touch panel 10 according to another exemplary embodiment includes the base film 120, the transparent electrode pattern layer 130, the wiring pattern layer 140, and the passivation layer 220.

In this case, opposite ends of the base film 120 in the same direction as the stretched direction SD1 are provided with heat treated regions A. In the heat treated region A, the stretched structure in the base film 120 is randomly changed by a heat treatment process, even though cracks may occur at both ends of the base film 120. This results in a change in the the cross direction of cracks, and thus, the crack occurring region may be remarkably reduced in size.

The heat treated region A may be formed to overlap the end of the transparent electrode pattern layer 130.

A material, a structure, and the like of other components in the touch panel according to this exemplary embodiment, that is, the transparent electrode pattern layer 130, the wiring pattern layer 140, and the passivation layer 220 are the same as described above and therefore the description thereof will be omitted herein. Further, features other than the feature of the heat treated regions A being disposed at both ends of the base film 120 are the same as the foregoing description.

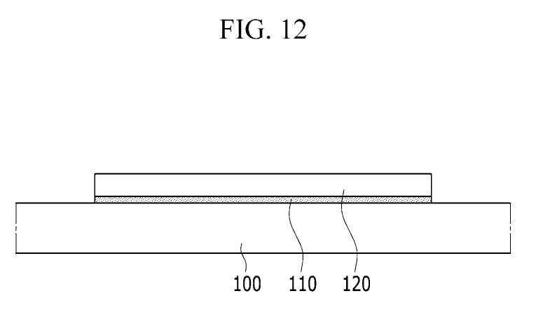

FIGS. 12 to 14 are diagrams sequentially illustrating a process of forming the touch panel of FIG. 10.

As illustrated in FIG. 12, the base film 120 is attached on the substrate 100 by adhesive 110.

As illustrated in FIG. 13, a predetermined region of opposite ends in the same direction as the stretched direction SD1 of the base film 120 is heat treated by using a heat treatment apparatus 500.

The heat treating process may be performed in a range from 130° C. to 270° C. for 5 to 10 seconds. When the heat treatment temperature and time meet these conditions, the stretched structure of the inside of the film is randomly changed without the base film 120 being damaged, and thus, it is possible to prevent the crack C from being enlarged and progressing from the ends of the base film 120 to the internal region.

To aid in understanding, FIG. 14 illustrates a plan view of the heat treated region A formed at opposite ends in the same direction as the stretched direction SD1 of the base film 120.

The transparent electrode pattern layer 130, the wiring pattern layer 140, and the passivation layer 220 are formed on the base film 120 in which the heat treated region is formed, by the same method as the foregoing method. The substrate 100 is removed, and as a result, the touch panel having the cross section structure as illustrated in FIG. 11 may be manufactured.

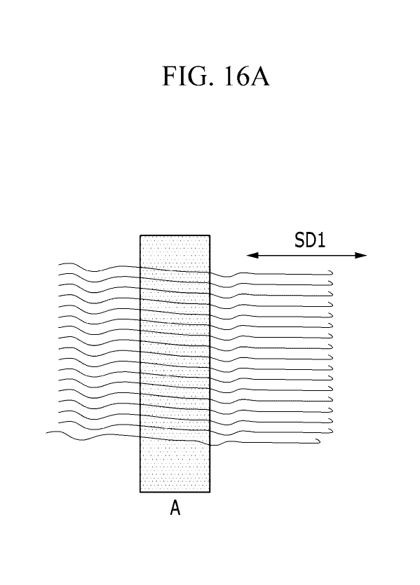

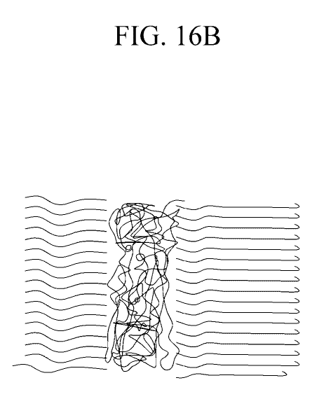

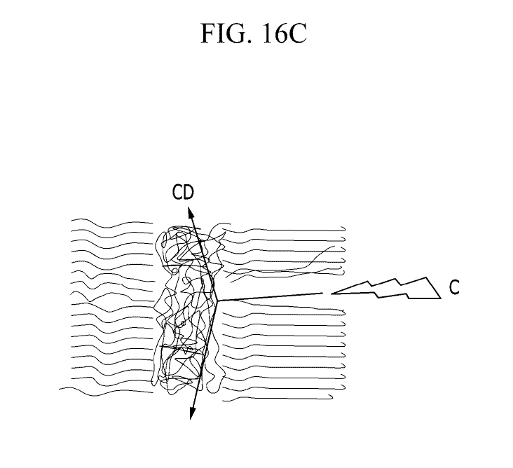

Meanwhile, FIGS. 16A, 16B, and 16C are enlarged views of the process of suppressing cracks from occurring at one end of the base film 120 of FIG. 11. Because the stretched structure in the base film 120 is randomly changed by the heat treating process as described above, as illustrated in FIGS. 16A, 16B, and 16C, when cracks occur at the ends of the base film 120, the cross direction CD of the crack C may be changed. Therefore, in the touch panel according to another exemplary embodiment of the present invention using the above effect, it is possible to effectively prevent cracks occurring at both ends of the base film 120 from progressing into the film and enlarged along the stretched direction SD1.

According to the touch panel and the method for manufacturing the same according to exemplary embodiments, it is possible to effectively prevent cracks from being formed at opposite ends in the same direction as the stretched direction of the base film included in the touch panel.

Although certain exemplary embodiments and implementations have been described herein, other embodiments and modifications will be apparent from this description. Accordingly, the inventive concept is not limited to such embodiments, but rather to the broader scope of the presented claims and various obvious modifications and equivalent arrangements.

What is claimed is:

1. A touch panel, comprising:
a uniaxially oriented base film; and
a transparent electrode pattern layer disposed on the base film,
wherein end protective films that are uniaxially oriented in a direction perpendicular to a stretched direction of the base film are attached to opposite ends of the base film in the same direction as the stretched direction.

2. The touch panel of claim 1, wherein the end protective film is attached to cover side walls of both ends of the base film.

3. The touch panel of claim 1, wherein the end protective film comprises at least one of a polycarbonate (PC) film, a polyethyleneterephthalate (PET) film, a polyethylenenaphthalate (PEN) film, a polyarylate (PAR) film, a polyetherimide (PEI) film, a polyethersulfone (PES) film, and a polyimde (PI) film.

4. The touch panel of claim 1, further comprising:
a wiring pattern layer disposed on the transparent electrode pattern layer and connected to a transparent electrode pattern; and
a passivation layer disposed on the transparent electrode pattern layer and the wiring pattern layer.

5. The touch panel of claim 1, wherein the uniaxially oriented base film comprises at least one of a polycarbonate (PC) film, a polyethyleneterephthalate (PET) film, a polyethylenenaphthalate (PEN) film, a polyarylate (PAR) film, a polyetherimide (PEI) film, a polyethersulfone (PES) film, and a polyimide (PI) film.

6. The touch panel of claim 1, wherein the base film and the end protective film comprise the same material.

7. A touch panel, comprising:
a uniaxially oriented base film; and
a transparent electrode pattern layer disposed on the base film,
wherein opposite ends of the base film in the same direction as a stretched direction are provided with heat treated regions.

8. The touch panel of claim 7, wherein the heat treated region overlaps an end of the transparent electrode pattern layer.

9. The touch panel of claim 7, further comprising:
a wiring pattern layer disposed on the transparent electrode pattern layer and connected to a transparent electrode pattern; and
a passivation layer disposed on the transparent electrode pattern layer and the wiring pattern layer.

10. The touch panel of claim 7, wherein the uniaxially oriented base film comprises at least one of a polycarbonate (PC) film, a polyethyleneterephthalate (PET) film, a polyethylenenaphthalate (PEN) film, a polyarylate (PAR) film, a polyetherimide (PEI) film, a polyethersulfone (PES) film, and a polyimide (PI) film.

11. A method for manufacturing a touch panel, comprising:
attaching a uniaxially oriented base film to a substrate; and
heat treating predetermined regions of opposite ends in the same direction as a stretched direction of the base film.

12. The method of claim 11, wherein the heat treating is performed in a temperature range of 130° C. to 270° C. for 5 to 10 seconds.

13. The method of claim 11, further comprising:
forming a transparent electrode pattern layer on the heat treated base film;
forming a wiring pattern layer connected to a transparent electrode on the transparent electrode pattern layer; and
forming a passivation layer on the transparent electrode pattern layer and the wiring pattern layer.
